(19) United States
(12) Patent Application Publication
(10) Pub. No.: US 2015/0155517 A1
(43) Pub. Date: Jun. 4, 2015

(54) ORGANIC LIGHT-EMITTING DEVICE

(71) Applicant: OSRAM OLED GmbH, Regensburg (DE)

(72) Inventors: Erwin Lang, Regensburg (DE); Guenter Schmid, Hemhofen (DE)

(73) Assignee: OSRAM OLED GMBH, Regensburg (DE)

(21) Appl. No.: 14/413,225

(22) PCT Filed: May 28, 2013
(86) PCT No.: PCT/EP2013/060963

§ 371 Date: Jan. 6, 2015

(30) Foreign Application Priority Data
Jul. 6, 2012 (DE) 102012211869.1

(51) Int. Cl. H01L 51/50; H01L 51/52

(52) U.S. Cl. CPC H01L 51/5012; H01L 51/5203

(57) ABSTRACT

The invention relates to an organic light-emitting component, having a substrate (1), on which an organic, functional layer stack (9) is arranged between two electrodes (2, 6, 10), of which at least one electrode (2, 6, 10) is designed to be translucent, wherein the organic, functional layer stack (9) has at least one light-emitting layer (4, 41, 42) and directly adjacent to at least one of the electrodes (2, 6, 10), a charge-producing layer (30, 50, 90), which forms a tunnel transition.

This patent application claims priority from German patent application 10 2012 211 869.1, the disclosure content of which is hereby included by reference.

An organic light-emitting device is provided.

An organic light-emitting diode (OLED) conventionally comprises at least one electroluminescent organic layer between two electrodes, which take the form of an anode and a cathode and by means of which charge carriers, i.e. electrons and holes, can be injected into the electroluminescent organic layer. High efficiency and long-life OLEDs may be produced in a manner similar to conventional inorganic light-emitting diodes by means of conductivity doping using a p-i-n junction, as described for example in the document R. Meerheim et al., Appl. Phys. Lett. 89, 061111 (2006). Here the charge carriers, i.e. the holes and electrons, are injected from the p- and n-doped layers purposefully into the intrinsically formed electroluminescent layer, where they form excitons, which lead to the emission of a photon on radiant recombination. The voltage drop over the electron- and hole-transport layers should be as low as possible and injection of the charge carriers from the two electrode materials should be as efficient as possible, so as to prevent an additional voltage drop and thus a loss in efficiency.

Previous approaches to solving the problem of optimising the voltage drop are based for example on the use of a p-doped layer at the boundary surface with the anode for efficient hole injection and for efficient hole transport of the holes to the electroluminescent layer and on the use of n-doped layers at the counter-electrode, i.e. the cathode, for efficient electron injection and for efficient electron transport to the electroluminescent layer, as described for example in the documents T. Uchida et al., Thin Solid Films 496, pp. 75-80 (2006) and M. Pfeiffer et al., Org. Elect. 4, pp. 21-26 (2003).

If, for instance in the production of transparent OLEDs, for example indium-tin oxide is used both as the anode and the cathode material, it is however possible to observe a voltage rise, which according to studies by the inventors may amount to more than 30% compared with an OLED of identical construction which emits only on one side and for example comprises an Al or Ag cathode. Such a voltage drop leads to a corresponding reduction in efficiency for transparent OLED devices, which cannot however be explained by optical phenomena such as cavity-related effects.

Such a loss in efficiency may be observed not only if both electrodes consist for example of indium-tin oxide, but also in cases where a layer combination for example of an indium-tin oxide layer and an Ag layer is used, as described for example in document DE 102009034822 A1, even if the indium-tin oxide layer has been applied only in very thin layers of 1 to 10 nm underneath a very thin Ag film.

Further approaches to solving the problem do not use any doped layers for electron or hole injection and arrange “injection layers” at the boundary surfaces with the respective electrodes, for example Ca, Ba, Li, lithium-(8-hydroxyquinoline) (Liq) or others on the cathode side, as described in the documents H. Peng et al., Appl. Phys. Lett. 88, 073517 (2006) and C.-W. Chen, Appl. Phys. Lett. 85 (13), 2469 (2004). On the anode side, for example hexaazatriphenylene carbonitrile (HAT-CN) or transition metal oxides such as for example molybdenum oxide or tungsten oxide are used directly adjacent the anode. Solvent-processed layers such as for example poly(3,4-ethylenedioxythiophene) (PEDOT) are used adjacent the anode for charge carrier injection or for hole transport.

It is at least one object of certain embodiments to provide an organic light-emitting device.

This object is achieved by a subject matter according to the independent claim. Advantageous embodiments and further developments of the subject matter are identified in the dependent claims and are revealed, moreover, by the following description and drawings.

According to at least one embodiment, an organic light-emitting device on a substrate comprises at least two electrodes, at least one of which is translucent and between which an organic functional layer stack is arranged. The organic functional layer stack comprises at least one organic light-emitting layer in the form of an organic electroluminescent layer, which generates light when the organic light-emitting device is in operation. The organic light-emitting device may in particular take the form of an organic light-emitting diode (OLED).

“Translucent” is used here and hereinafter to describe a layer which is transmissive to visible light. The translucent layer may here be transparent, i.e. clear, or at least partially light-scattering and/or partially light-absorptive, such that the translucent layer may for example also be diffusely or milkily translucent. A layer here described as translucent may particularly preferably be maximally transparent, such that in particular light absorption is as low as possible.

The organic functional layer stack may comprise layers with organic polymers, organic oligomers, organic monomers, organic small, non-polymeric molecules (“small molecules”) or combinations thereof. Materials suitable as materials for the organic light-emitting layer are materials which have radiation emission based on fluorescence or phosphorescence, for example polyfluorene, polythiophene or polyphenylene, or derivatives, compounds, mixtures or copolymers thereof. The organic functional layer stack may also comprise a plurality of organic light-emitting layers, which are arranged between the electrodes. The organic functional layer stack may moreover comprise a functional layer which takes the form of a hole transport layer, to allow effective hole injection into the at least one light-emitting layer. Materials which may prove advantageous for a hole transport layer are for example tertiary amines, carbazole derivatives, polyaniline doped with camphorsulfonic acid or polyethylenedioxythiophene doped with polystyrenesulfonic acid. The organic functional layer stack may further comprise a functional layer, which takes the form of an electron-transport layer. Furthermore, the layer stack may also comprise electron- and/or hole-blocking layers.

The substrate may for example comprise one or more materials in the form of a layer, a sheet, a film or a laminate, which are selected from glass, quartz, plastics, metal or silicon wafer. The substrate particularly preferably comprises or consists of glass, for example in the form of a glass layer, glass film or glass sheet.

With regard to the basic structure of an organic light-emitting device, for example in terms of the structure, the layer composition and the materials of the organic functional layer stack, reference is made to document WO 2010/066245 A1, which is hereby explicitly included by reference, in particular in relation to the structure of an organic light emitting device.

The two electrodes between which the organic functional layer stack is arranged may for example both be translucent, such that the light generated in the at least one light-emitting layer between the two electrodes may be emitted in both directions, i.e. in the direction of the substrate and in the direction away from the substrate. Furthermore, for example all the layers of the organic light-emitting component may be translucent, such that the organic light-emitting device forms a translucent and in particular a transparent OLED. It may furthermore also be possible for one of the two electrodes between which the organic functional layer stack is arranged to be non-translucent and preferably reflective, such that the light generated in the at least one light-emitting layer between the two electrodes may be emitted in just one direction by the translucent electrode. If the electrode arranged on the substrate is translucent and the substrate is also translucent, the term “bottom emitter” may also be used, while if the electrode arranged remote from the substrate is translucent, the term “top emitter” is used.

The organic functional layer stack of the organic light-emitting device described here further comprises a charge-generation layer immediately adjacent at least one of the electrodes. The term “charge-generation layer” is used here and hereafter to describe a layer sequence which takes the form of a tunnel junction and which is formed in general by a p-n junction. The charge-generation layer (CGL) in particular takes the form of a tunnel junction which is operated in the reverse direction and which may be used for effective charge separation and thus to “generate” charge carriers for the adjacent layers.

According to a further embodiment, the electrode directly adjoined by the charge-generation layer is translucent.

Furthermore, the charge-generation layer may also directly adjoin the organic light-emitting layer or directly adjoin a charge carrier-blocking layer between the charge-generation layer and the light-emitting layer.

According to a further embodiment, the charge-generation layer comprises an electron-conducting layer and a hole-conducting layer. Electron-conducting and hole-conducting may here and hereafter also be described as n-conductive and p-conductive respectively.

If the electrode directly adjoining the charge-generation layer takes the form of an anode, the charge-generation layer directly adjoining the electrode comprises an electron-conducting layer. If the electrode directly adjoining the charge-generation layer takes the form of a cathode, the charge-generation layer directly adjoining the electrode comprises a hole-conducting layer. If no charge-generation layer is arranged on the other electrode of the two electrodes between which the organic functional layer stack with the charge-generation layer is arranged, this means that, if the charge-generation layer is arranged directly on the anode, an electron-conducting layer adjoins each of the two electrodes while, if the charge-generation layer is arranged directly on the cathode, a hole-conducting layer is arranged on each of the two electrodes. In these cases either two electron-conducting or two hole-conducting layers thus form the respective boundary surfaces with the two electrodes.

In a particularly preferred embodiment, the organic light-emitting device comprises the charge-generation layer, in particular on the electrode taking the form of the cathode, which may in particular be translucent. The charge-generation layer comprises for example a hole-conducting layer directly adjacent the cathode, wherein the holes generated in the charge-generation layer are “transported away” via the cathode or are filled with electrons or recombine at the boundary surface with the cathode. The original electron injection from the cathode is thus solved by an inverse approach. In this case, a hole-conducting layer thus in each case forms the boundary layer with the two electrode materials, thus the two electrodes, which are for example both translucent and may be configured to comprise a transparent conductive oxide.

In a further particularly preferred embodiment, the organic light-emitting device comprises the charge-generation layer, in particular on the electrode taking the form of the anode, which may in particular be translucent. In this case the charge-generation layer preferably comprises an electron-conducting layer adjacent the anode, such that the injection and transport of holes from the anode into a hole-conducting layer, as with conventional OLEDs, are replaced by the inverse process and the electrons which are generated in the charge-generation layer are carried away towards the anode. In this case, through introduction of the charge-generation layer on the anode side two electron-conducting layers form the boundary surfaces with the two electrodes.

It is particularly preferable for at least one of the electron-conducting layer and the hole-conducting layer of a charge-generation layer adjoining an anode to comprise a dopant in a matrix material. Examples of such a doped electron-conducting or hole-conducting layer are listed further below.

In a further particularly preferred embodiment, the charge-generation layer is arranged adjacent the electrode taking the form of an anode and comprises an electron-conducting layer adjacent the anode which comprises a matrix material with a dopant.

Furthermore, the two charge carrier-conducting layers of a charge-generation layer adjoining an anode may each comprise a dopant in a matrix material.

According to a further embodiment, the translucent electrode comprises a transparent conductive oxide or consists of a transparent conductive oxide. Transparent conductive oxides (TCO) are transparent, conductive materials, generally metal oxides, such as for example zinc oxide, tin oxide, cadmium oxide, titanium oxide, indium oxide, indium-tin oxide (ITO) or aluminium zinc oxide (AZO). In addition to binary metal-oxygen compounds, such as for example ZnO, SnO₂ or In₂O₃, ternary metal-oxygen compounds, such as for example Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the TCO group. Furthermore, TCOs do not necessarily correspond to a stoichiometric composition and may also be p- or n-doped.

According to a further embodiment, the electrode directly adjoining the charge-generation layer comprises a transparent conductive oxide directly adjoining the charge-generation layer. This may mean, for example, that the electrode directly adjoining the charge-generation layer comprises a layer of a TCO directly adjoining the charge-generation layer.

Furthermore, the translucent electrode may comprise a metal layer with a metal or an alloy, for example with one or more of the following materials: Ag, Pt, Au, Mg, Ag:Mg. Other metals are moreover also possible. Use is particularly preferably made of one or more metals which are stable in air and/or which are self-passivating, for example through the formation of a thin protective oxide layer. In this case, the metal layer has such a small thickness that it is at least in part permeable to the light generated by the at least one organic light-emitting layer when in operation, for example a thickness of less than or equal to 50 nm.

The electrode which directly adjoins the charge-generation layer may, for example, comprise a metal directly adjacent the charge-generation layer.

The translucent electrode may also comprise a combination of at least one or more TCO layers and at least one translucent metal layer.

According to a further embodiment, the further electrode of the two electrodes between which the organic functional layer stack with the charge-generation layer is arranged is also translucent. The translucent further electrode may comprise features and materials as described above in connection with the translucent electrode. In particular, all the electrodes of the organic light-emitting device may be translucent and comprise one or more of the above-stated materials.

According to a further embodiment, the further electrode of the two electrodes between which the organic functional layer stack with the charge-generation layer is arranged is reflective and for example comprises a metal which may be selected from aluminium, barium, indium, silver, gold, magnesium, calcium and lithium as well as compounds, combinations and alloys thereof. In particular, the reflective further electrode may comprise Ag, Al or alloys therewith, for example Ag:Mg, Ag:Ca, Mg:Al. The reflective electrode may in this case in particular take the form of a cathode. Alternatively or in addition, the reflective electrode may also comprise one or more of the above-stated TCO materials.

The electrodes may in each case be of large-area configuration. This allows large-area emission of the light generated in the at least one organic light-emitting layer. “Large-area” may mean that the organic light-emitting device comprises an area of greater than or equal to a few square millimetres, preferably greater than or equal to one square centimeter and particularly preferably greater than or equal to one square decimeter.

According to a further embodiment, the organic functional layer stack directly adjacent both of the two electrodes between which the organic functional layer stack is arranged in each case comprises a charge-generation layer. In this case an electron-conducting layer adjoins the electrode taking the form of an anode and a hole-conducting layer adjoins the electrode taking the form of a cathode. The organic functional layer stack with the two electrodes in this case forms an “inverted” OLED, in which injection of the corresponding charge carrier type is replaced in each case by the above-described inverse process.

According to a further embodiment, the organic functional layer stack between the electrodes comprises at least two organic light-emitting layers, between which a further charge-generation layer may furthermore be arranged. Such an organic functional layer stack with the electrodes may also be designated a “stacked OLED”, in which a plurality of organic OLED units are accommodated vertically one above the other by charge-generation layers arranged therebetween. Stacking a plurality of organic light-emitting layers on top of one another makes it possible on the one hand to generate mixed light. Furthermore, in multiply stacked OLEDs it is possible to achieve markedly longer service lives with virtually identical efficiency and identical luminance relative to OLEDs with just one light-emitting layer, since several times the luminance can be achieved at identical current densities.

According to a further embodiment, a further organic functional layer stack with a further electrode thereover are arranged over the two electrodes with the organic functional layer stack arranged therebetween and the at least one charge-generation layer. In other words, the organic light-emitting device comprises at least three electrodes, wherein an organic functional layer stack is arranged between in each case neighbouring electrodes. In this way, the electrode arranged between the organic functional layer stack and the further organic functional layer stack takes the form of an intermediate electrode, which may be directly driven for example to control the colour of emission of the organic light-emitting device in the case of different light-emitting layers in the organic functional layer stacks. In particular, directly adjacent at least one of the two electrodes between which the further organic functional layer stack is arranged, the further organic functional layer stack may comprise a further charge-generation layer.

According to a further embodiment, the organic light-emitting device comprises a charge-generation layer directly adjacent each electrode on the side facing an organic light-emitting layer.

For example, the charge-generation layer may comprise as a hole-conducting layer a p-doped layer comprising an inorganic or organic dopant in an organic hole-conducting matrix. Examples of suitable inorganic dopants are transition metal oxides such as for instance vanadium oxide, molybdenum oxide or tungsten oxide. Examples of suitable organic dopants are tetrafluorotetracyanoquinodimethane (F4-TCNQ) or copper pentafluorobenzoate (Cu(I)pFBz). Furthermore, examples of suitable organic dopants are transition metal complexes. These may preferably comprise a central atom, for example Cu, with ligands, for example acetylacetonate (acac). Furthermore, copper complexes, for example copper carboxylates, are suitable examples. Such and further dopants are described in documents WO 2011/033023 A1 and WO 2011/120709 A1, the respective disclosure content of which is hereby included in its entirety by reference in relation to the dopants described therein.

Furthermore, metal complexes with bismuth and/or chromium are also suitable, as described in as yet unpublished applications DE 102012209523.3 and DE 102012209520.9, the respective disclosure content of which is hereby included in its entirety by reference in relation to the dopants described therein.

As an electron-conducting layer, the charge-generation layer may for example comprise an n-doped layer with an n-dopant in an organic electron-conducting matrix, for example a metal with a low work function such as for example Cs, Li, Ca, Na, Ba or Mg or compounds thereof, for example Cs₂CO₃ or Cs₃PO₄. Such and further dopants are described, for example, in document WO 2011/039323 A2, the respective disclosure content of which is hereby included in its entirety by reference in relation to the dopants described therein.

Furthermore, organic p- and n-dopants are also obtainable from Novaled under the trade names NDP-2, NDP-9, NDN-1, NDN-26.

According to a further embodiment, the charge-generation layer in each case comprises a dopant in a matrix material as hole-conducting layer and as electron-conducting layer. For example, such a charge-generation layer may be arranged directly adjacent an electrode taking the form of an anode.

According to a further embodiment, the electron-conducting layer and/or the hole-conducting layer of the charge-generation layer do not comprise any dopant in a matrix material, but rather are formed in each case by an undoped organic material with the corresponding charge carrier-conducting property.

According to a further embodiment, the charge-generation layer comprises an undoped interlayer between the electron-conducting layer and the hole-conducting layer. The interlayer may for example be formed by a metal oxide, for instance VOₓ, for example V₂O₅, MoOₓ, WOₓ, Al₂O₃, indium-tin oxide, SnOₓ and/or ZnOₓ or an organometallic compound such as for instance phthalocyanine (PcH₂), for example copper phthalocyanine (CuPc), vanadyl phthalocyanine (VOPc), titanyl phthalocyanine (TiOPc) and furthermore have a thickness of a few nanometres up to a few tens of nanometres, or consist thereof. Furthermore, the interlayer may comprise a thin metal layer, for example with a thickness of greater than or equal to 0.1 nm and less than or equal to 5 nm, with one or more of Al, Ag, Cu or Au, or consist thereof. The interlayer may furthermore also comprise two or more of the above-stated materials, for example in the form of a mixed layer, which is composed of two of the above-stated materials, for instance CuPc and VOPc or Al and Ag or WOₓ and MoOₓ. The interlayer may for example suppress a reaction to completion of the sometimes highly reactive layers of the undoped material for the electron-conducting layer and/or the hole-conducting layer.

For example, the charge-generation layer may comprise HAT-CN as the hole-conducting layer, VOPc as the interlayer and NDN-26 as the electron-conducting layer. Alternatively, organic materials previously stated for the dopants may also be used.

Furthermore, a combination of an organic undoped layer as one of the charge carrier-conducting layers with a layer of a transition metal oxide or a metal with a high conductivity as the other one of the charge carrier-conducting layers is possible. For example, the charge-generation layer may comprise a hole-conducting layer of HAT-CN and an electron-conducting layer of MgAg or one of the above-stated transition metal oxides.

According to a further embodiment, an optical layer, in particular in the form of an antireflective layer and/or a scattering layer, is applied to one side of the translucent electrode remote from the at least one light-emitting layer. A material with a high refractive index of greater than or equal to 1.6 and preferably of greater than or equal to 1.8 or even greater than or equal to 2.0 may for example be used as the antireflective layer, for example titanium oxide, zinc oxide, tantalum oxide and/or hafnium oxide. A first material with a first refractive index for example in which a second particulate material with a second, different refractive index is embedded may be used as scattering layer. The first material may for example take the form of a plastics material, while the second particulate material is formed for example by an oxide, in particular one or more of the above-stated metal oxides.

An encapsulation arrangement may moreover also be arranged over the electrodes and the organic layers. The encapsulation arrangement may for example take the form of a glass cover or, preferably, the form of a thin-film encapsulation.

A glass cover, for example in the form of a glass substrate, which may comprise a cavity, may be adhesively bonded to the substrate by means of an adhesive layer or of a glass solder or fused together with the substrate. A moisture-absorbing substance (getter), for example comprising zeolite, may furthermore be adhesively bonded in the cavity, to bind moisture or oxygen which may penetrate through the adhesive. Furthermore, an adhesive containing a getter material may be used to fasten the cover to the substrate.

An encapsulation arrangement configured as a thin-film encapsulation is here understood to mean a device which is suitable for forming a barrier against atmospheric substances, in particular against moisture and oxygen and/or against further harmful substances such as for instance corrosive gases, for example hydrogen sulfide. The encapsulation arrangement may to this end comprise one or more layers each with a thickness of less than or equal to a few 100 nm.

In particular, the thin-film encapsulation may comprise or consist of thin layers which are applied for example by means of an atomic layer deposition (ALD) method. Suitable materials for the layers of the encapsulation arrangement are for example aluminium oxide, zinc oxide, zirconium oxide, titanium oxide, hafnium oxide, lanthanum oxide or tantalum oxide. The encapsulation arrangement preferably comprises a layer sequence with a plurality of the thin layers which each comprise a thickness of between one atom layer and 10 nm, limit values included.

As an alternative or in addition to thin layers produced by ALD, the encapsulation arrangement may comprise at least one or a plurality of further layers, i.e. in particular barrier layers and/or passivation layers, which are deposited by thermal vapour deposition or by a plasma-enhanced process, for instance sputtering or plasma-enhanced chemical vapour deposition (PECVD). Suitable materials for this purpose may be the above-stated materials together with silicon nitride, silicon oxide, silicon oxynitride, indium tin oxide, indium zinc oxide, aluminium-doped zinc oxide, aluminium oxide and mixtures and alloys of the stated materials. The one or the plurality of further layers may for example each have a thickness of between 1 nm and 5 μm and preferably between 1 nm and 400 nm, limit values included.

Thin-film encapsulations are known for example in documents WO 2009/095006 A1 and WO 2010/108894 A1, the respective disclosure content of which is hereby included in its entirety by reference.

In the case of the organic light-emitting device described here, which may take the form for example of a lighting device in the form of an OLED luminaire, the charge carrier injection into the organic functional layer stack is advantageously replaced at least at one electrode, in particular at the translucent electrode, by the above-described inverse process. In this way, a reduction of the voltage drop at such boundary surfaces may be achieved. As a consequence, a transparent conductive oxide such as for example ITO or AZO may be used as the material for the translucent electrode, alone or in combination with a metal such as for example Ag. In particular, the translucent electrode may also form the “top electrode” remote from the substrate. This allows OLEDs to be produced with very high transparency values, so also enabling the efficiency of such a transparent device to be increased. This may also have a positive effect on the service life of the organic light-emitting device and the possibility arises of producing novel OLED devices.

Further advantages, advantageous embodiments and further developments are revealed by the following exemplary embodiments described below in conjunction with the figures, in which:

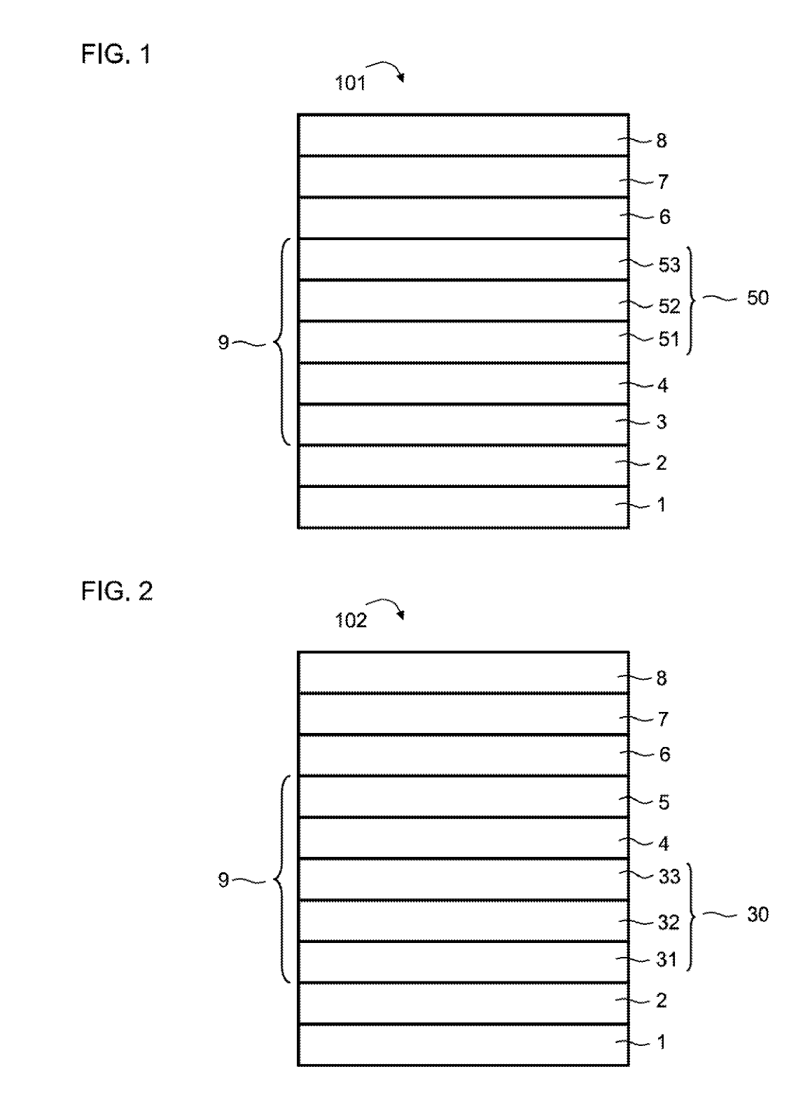

FIG. 1 is schematic representation of an organic light-emitting device according to one exemplary embodiment,

FIG. 2 is a schematic representation of an organic light-emitting device according to a further exemplary embodiment,

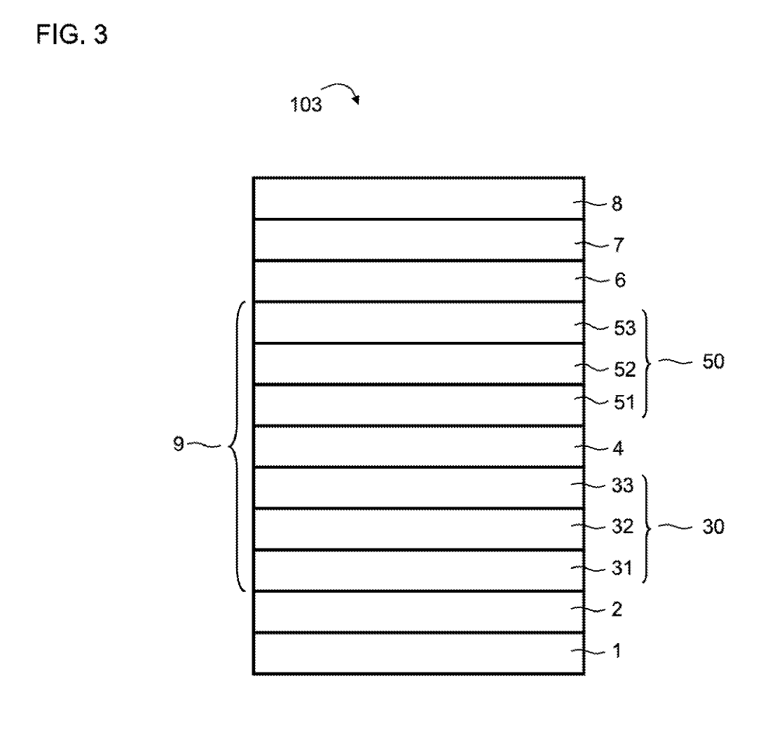

FIG. 3 is a schematic representation of an organic light-emitting device according to a further exemplary embodiment,

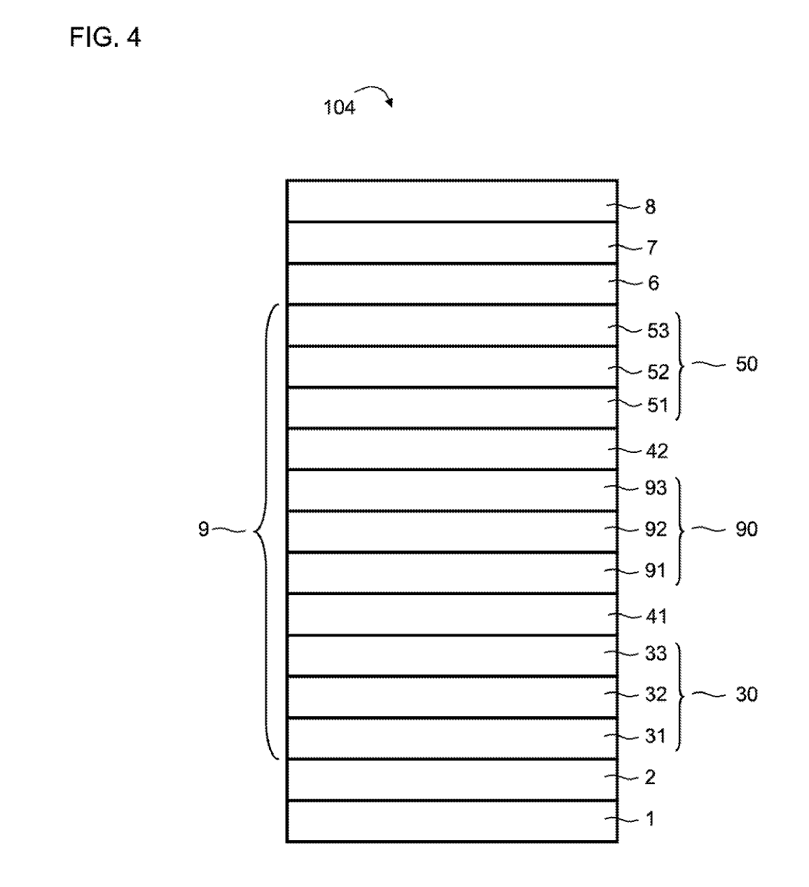

FIG. 4 is a schematic representation of an organic light-emitting device according to a further exemplary embodiment and

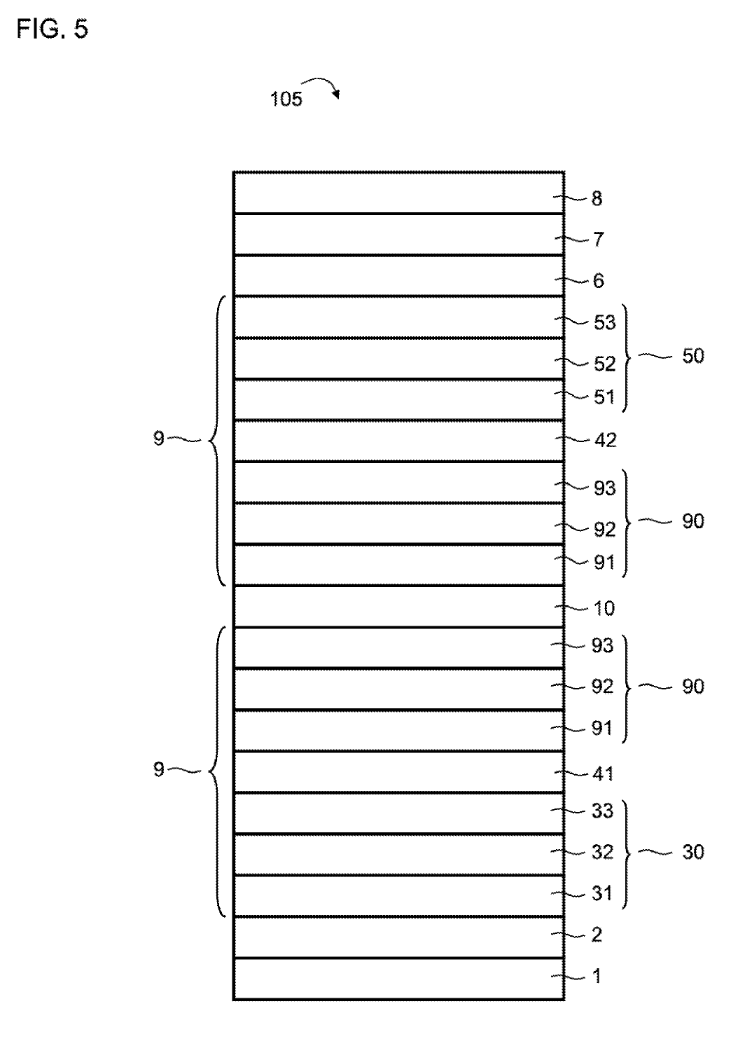

FIG. 5 is a schematic representation of an organic light-emitting device according to a further exemplary embodiment.

In the exemplary embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

FIG. 1 shows an exemplary embodiment of an organic light-emitting device 101. This comprises a substrate 1, on which an organic functional layer stack 9 with at least one organic light-emitting layer 4 for generating light is arranged between two electrodes 2, 6. To this end, the electrode 2 takes the form of an anode and the electrode 6 the form of a cathode.

In the exemplary embodiment shown, at least the electrode 6 arranged remote from the substrate 1 is translucent. In this way, the light generated in the organic light-emitting layer 4 when in operation is emitted in the direction away from the substrate 1. To this end, the electrode 6 comprises a transparent conductive oxide (TCO) and/or a translucent metal. For example, the translucent electrode 6 may be formed by a layer of a TCO such as for example indium-tin oxide (ITO) or aluminium-zinc oxide (AZO). Furthermore, the translucent electrode 6 may also take the form of a plurality of layers, for example a layer of a TCO such as for instance the above-stated ITO or AZO and a layer of a translucent metal such as for example silver. In the latter case, viewed from the substrate 1 the metal layer is applied to the layer of the TCO, such that the layer of the TCO faces the organic functional layer stack 9.

Alternatively, the translucent electrode 6 may for example also be formed of a translucent metal layer, for example Ag and/or Al, or a further or other one of the metals mentioned above in the general part or at least comprise one such layer directly adjacent the organic functional layer stack 9.

It is possible, as shown in FIG. 1, to arrange over the translucent electrode 6 an optical layer, for example in the form of an antireflective layer, which for example has a high refractive index, in order to allow efficient light outcoupling.

Furthermore, an encapsulation arrangement 8, preferably in the form of a thin-film encapsulation, may be applied over the translucent electrode 6, in order to protect the organic light-emitting device 101 and in particular the layers of the organic functional layer stack 9 and the electrodes 2, 6 from harmful materials from the environment, such as for example moisture and/or oxygen and/or other corrosive substances such as for instance hydrogen sulfide. The encapsulation arrangement 8 may, to this end, as described in the general part, comprise one or more thin layers, which are applied for example by means of an atomic layer deposition method and which comprise for example one or more of the materials aluminium oxide, zinc oxide, zirconium oxide, titanium oxide, hafnium oxide, lanthanum oxide and tantalum oxide. The encapsulation arrangement 8 may, moreover, for example comprise, on layers forming a thin-film encapsulation, a mechanical protection in the form of a plastics layer and/or a laminated-on glass layer, whereby for example scratch protection may be achieved.

In the exemplary embodiment shown, both the substrate 1 and the further electrode 2, which is arranged between the organic functional layer stack 9 and the substrate 1, are likewise translucent, such that the organic light-emitting device 101 emits on both sides and preferably is also translucent. To this end, the substrate 1 comprises a translucent material, for example glass or a plastics material provided with a suitable encapsulation arrangement, for example in the form of a coated plastics film. The further translucent electrode 2 may preferably comprise a transparent conductive oxide. Alternatively, it is also possible that the further electrode 2 is not translucent but preferably reflective, such that the light generated in the light-emitting layer 4 when in operation may be emitted in the direction of the translucent electrode 6. In this case the organic light-emitting device takes the form of a “top emitter”.

The light-emitting layer 4 for example comprises an electroluminescent material mentioned above in the general part. Furthermore, charge carrier blocking layers may be provided, between which the organic light-emitting layer is arranged. A hole-conducting layer, for example a hole-transport layer and/or a hole-injection layer is arranged between the light-emitting layer 4 and the electrode 2, which in the exemplary embodiment shown takes the form of an anode.

Directly adjacent the translucent electrode 6 there is arranged a charge-generation layer 50, which is formed by a tunnel junction and which to this end comprises an electron-conducting layer 51 and a hole-conducting layer 53. An interlayer 52 is provided between the charge carrier-conducting layers 51 and 53. For example, the electron-conducting layer and/or the hole-conducting layer 53 may in each case comprise a matrix material in which a correspondingly conductive dopant is embedded. The electron-conducting layer 51 may for example comprise as its electron-conducting dopant a metal with low work function such as for example Cs, Li, Ca, Na or Mg or compounds thereof such as for instance Cs₂CO₃ or Cs PO₄ in an organic electron-conducting matrix. The hole-conducting layer 53 may comprise in an organic hole-conducting matrix material for example an organic dopant such as for instance a transition metal oxide, for example vanadium oxide, molybdenum oxide or tungsten oxide, or an organic dopant such as for example F4-TCNQ or Cu(I)pFBz.

The interlayer 52 may for example be undoped and for instance formed by a metal, metal oxide or a phthalocyanine, for example Al, Ag, Cu, Au, VOₓ, MoOₓ, WOₓ, Al₂O₃, indium-tin oxide, SnOₓ, ZnOₓ, CuPc, VOPc or TiOPc. Furthermore, the interlayer 52 may for example also comprise at least two materials or be composed thereof, for example in the form of a mixed layer with CuPc and VOPc or Al and Ag or WOₓ and MoOₓ or other combinations of the phthalocyanines, metal oxides and metals mentioned previously or above in the general part. The interlayer 52 may for example also be provided to prevent a chemical reaction between the organic materials of the hole-conducting layer 53 and the electron-conducting layer 51.

This may be necessary in particular when the charge-generation layer 50 for example in each case comprises as its electron-conducting layer 51 and its hole-conducting layer 53 an undoped, correspondingly conductive organic material, for example the material NDN-26 obtainable from Novaled as the electron-conducting material and the material HAT-CN as the hole-conducting material, VOPc preferably being arranged therebetween as the interlayer 52.

Alternatively, if the material is suitably selected, the interlayer 52 may also be omitted. In particular, the combination of a charge carrier-conducting organic undoped layer together with a layer of a transition metal oxide or a conductive metal may also be formed as the charge-generation layer 50, for example HAT-CN as the hole-conducting layer 53 and MgAg or a transition metal oxide as the electron-conducting layer 51. Because, as is apparent in FIG. 1, the hole-conducting layer 53 of the charge-generation layer 50 directly adjoins the translucent electrode 6, which takes the form of the cathode, the holes generated in the charge-generation layer 50 are transported away via the translucent electrode 6 or filled with electrons at the boundary surface. Electrons are correspondingly injected into the organic light-emitting layer 4 by the electron-conducting layer 51.

In the case of the organic light-emitting device 101 shown in FIG. 1, two hole-conducting layers, namely the hole-conducting layer 3 and the hole-conducting layer 53 of the charge-generation layer 50, thus form the boundary surfaces with the two electrodes 2, 6. In particular, the charge-generation layer 50 on the translucent electrode 6 taking the form of the cathode may prevent voltage losses which may arise in a conventional structure with a translucent cathode formed from a TCO or a metal-TCO combination and an electron-conducting layer directly adjoining said cathode.

The exemplary embodiments disclosed below constitute variations and modifications of the exemplary embodiment shown in FIG. 1, such that the following description relates substantially to the differences from the exemplary embodiment of FIG. 1.

FIG. 2 shows a further exemplary embodiment of an organic light-emitting device 102 which, in comparison with the previous exemplary embodiment, comprises a charge-generation layer 30 directly adjacent the electrode 2 arranged between the substrate 1 and the organic light-emitting layer 4. An electron-conducting layer is arranged between the organic light-emitting layer 4 and the further electrode 6. The electrode 2 may preferably be translucent. The further electrode 6, which is arranged on the side of the organic functional layer stack 9 remote from the substrate, may be translucent or indeed reflective. Accordingly, the organic light-emitting device 102 may for example take the form of a “bottom emitter” or indeed, as in the previous exemplary embodiment, of a transparent OLED. In the case of an organic light-emitting device 102 in the form of a bottom emitter, the optical layer 7 shown in FIG. 2 may also be omitted.

The charge-generation layer 30, which directly adjoins the electrode 2 taking the form of an anode, comprises an electron-conducting layer 31, an interlayer 32 and a hole-conducting layer 33. The organic light-emitting device 102 thus comprises two electron-conducting layers 31, in the organic functional layer stack 9, which form the boundary surfaces with the electrodes 2, 6, respectively.

The layers of the charge-generation layer 30 may for example be constructed as described in relation to FIG. 1. Particularly preferably, the charge-generation layer 30 comprises in each case as electron-conducting layer 31 and as hole-conducting layer 33 a dopant in a matrix material, the materials possibly being as described for example above in the general part.

As already described in relation to FIG. 1 and the translucent electrode 6 taking the form of the cathode, it is possible, through introduction of the charge-generation layer on the anode side, i.e. in direct contact with the electrode 2, to replace the injection and transport of holes into a hole-conducting layer, as is usual with conventional OLEDs, by the inverse process, i.e. in the organic light-emitting device 102 electrons which are generated in the electron-conducting layer 31 of the charge-generation layer 30 must be removed to the electrode 2 embodied as the anode.

As an alternative to the previously described exemplary embodiments, in which the substrate-side electrode 2 takes the form of the anode and the electrode 6 arranged over the organic functional layer stack 9 takes the form of the cathode, the electrode 2 may also take the form of the cathode and the electrode 6 that of the anode, wherein in this case the sequences of the charge carrier-conducting layers of the charge-generation layers 30, 50 are also reversed.

FIG. 3 shows a further exemplary embodiment of an organic light-emitting device 103, which represents a combination of the two previous exemplary embodiments and in which a charge-generation layer 30, 50 is arranged on both sides of the organic light-emitting layer 4. In other words, the organic functional layer stack 9 comprises the charge-generation layer 30 directly adjacent the electrode 2 and the charge-generation layer 50 directly adjacent the electrode 6.

FIG. 4 shows a further exemplary embodiment of an organic light-emitting device 104, which comprises a plurality of organic light-emitting layers 41, 42 between the electrodes 2, 6, two such layers being shown purely by way of example. A further charge-generation layer 90 with charge carrier-conducting layers 91, 93 and an interlayer 92 is arranged between the organic light-emitting layers 41, 42. The charge-generation layer 90 may for example be configured like the charge-generation layer 30, 50.

FIG. 5 shows a further exemplary embodiment of an organic light-emitting device 105, which, in comparison with the previous exemplary embodiment, comprises a further electrode 10 between the organic light-emitting layers 41, 42. In other words, an organic functional layer stack 9 with the organic light-emitting layer 41 is arranged between the electrodes 2, 10 and a further organic functional layer stack with the organic light-emitting layer 42 is arranged between the electrodes 10, 6.

At least two of the electrodes 2, 6, 10 are translucent. The electrode 10 takes the form of an intermediate electrode, which may be purposefully driven, whereby for example control of the intensity emitted in each case by the light-emitting layers 41, 42 may be adjusted, such that for example the colour of emission of the organic light-emitting device 105 may be controlled. Directly adjacent the electrode 10 the organic light-emitting device comprises a charge-generation layer 90 in each case on both sides. Alternatively, it may also be possible for the electrode 10, as with conventional OLEDs, to emit charge carriers directly via charge carrier-conducting layers into the light-emitting layers 41, 42.

The exemplary embodiments of the organic light-emitting device 101, 102, 103, 104 and 105 shown in the figures and features thereof may also be combined together in further exemplary embodiments. Moreover, the exemplary embodiments shown may alternatively or additionally comprise further features according to the embodiments in the general part.

The description made with reference to exemplary embodiments does not restrict the invention to these embodiments. Rather, the invention encompasses any novel feature and any combination of features, including in particular any combination of features in the claims, even if this feature or this combination is not itself explicitly indicated in the claims or exemplary embodiments.

1. Organic light-emitting device with a substrate, on which an organic functional layer stack is arranged between two electrodes, of which at least one electrode is translucent, wherein the organic functional layer stack comprises at least one light-emitting layer and, directly adjacent to at least one of the electrodes, which takes the form of the cathode, a charge-generation layer, which is formed by a tunnel junction and which comprises an electron-conducting layer and a hole-conducting layer.

2. Device according to claim 1, wherein the charge-generation layer comprises a hole-conducting layer directly adjacent the electrode taking the form of the cathode.

3. Device according to claim 1, wherein the electron-conducting layer and/or the hole-conducting layer comprises a dopant in a matrix material.

4. Device according to claim 1, wherein the electron-conducting layer and/or the hole-conducting layer is formed by an undoped material.

5. Organic light-emitting device with a substrate, on which an organic functional layer stack is arranged between two electrodes, of which at least one electrode is translucent, wherein the organic functional layer stack comprises at least one light-emitting layer and, directly adjacent to at least one of the electrodes, which takes the form of the anode, a charge-generation layer, which is formed by a tunnel junction and which comprises an electron-conducting layer and a hole-conducting layer, of which at least one comprises a dopant in a matrix material.

6. Device according to claim 5, wherein the charge-generation layer comprises an electron-conducting layer directly adjacent the electrode taking the form of the anode.

7. Device according to claim 1, wherein the electrode directly adjacent the charge-generation layer comprises a transparent conductive oxide directly adjacent the charge-generation layer.

8. Device according to claim 1, wherein the electrode directly adjacent the charge-generation layer comprises a metal directly adjacent the charge-generation layer.

9. Device according to claim 1, wherein all the electrodes of the organic light-emitting device are translucent.

10. Device according to claim 1, wherein the organic functional layer stack in each case comprises a charge-generation layer directly adjacent both of the two electrodes.

11. Device according to claim 1, wherein the organic functional layer stack comprises at least two organic light-emitting layers between the electrodes, between which layers a further charge-generation layer is arranged.

12. Device according to claim 1, one of the preceding claims, wherein over the two electrodes with the organic functional layer stack arranged therebetween there are arranged a further organic functional layer stack thereover and wherein the further organic functional layer stack comprises a further charge-generation layer directly adjacent an electrode.

13. (canceled)

14. Device according to claim 1, wherein the charge-generation layer comprises an undoped interlayer between the electron-conducting layer and the hole-conducting layer.
